(19) United States
(12) Patent Application Publication
(10) Pub. No.: US 2013/0162270 A1
(43) Pub. Date: Jun. 27, 2013

(54) CAPACITANCE TYPE MEASURING DEVICE

(71) Applicant: HORIBA STEC, Co., Ltd., Kyoto-shi (JP)

(72) Inventors: Soutaro Kishida, Kyoto-shi (JP); Akira Kuwahara, Osaka-shi (JP); Takehisa Hataita, Kuse-gun (JP); Toshihiro Ikeyama, Kyoto-shi (JP)

(73) Assignee: HORIBA STEC, Co., Ltd., Kyoto-shi (JP)

(21) Appl. No.: 13/727,293

(22) Filed: Dec. 26, 2012

(30) Foreign Application Priority Data
Dec. 27, 2011 (JP) 2011-286328

(51) Int. Cl. G01R 27/26

(52) U.S. Cl. CPC G01R 27/2605
USPC 324/661; 324/679

(57) ABSTRACT

A capacitance type measuring device for measuring a physical quantity of an object to be measured by measuring a capacitance of a variable capacitor is provided, which achieves compactness, simplicity of structure, and improved measurement accuracy. The capacitance type measuring device may include a primary measuring circuit that is configured with the variable capacitor and a reference electronic element that is a reference to measure a capacitance of the variable capacitor, a secondary measuring circuit that has an impedance conversion element with sufficiently high input impedance and is connected to the primary measuring circuit, and a substrate in which a part or all of the each measuring circuit is formed. The high impedance circuit part may be formed between the variable capacitor and an impedance conversion element, and the reference electronic element may be embedded inside the substrate between a front surface and a rear surface thereof.

### FIELD OF THE INVENTION

The present invention relates to a capacitance type measuring device that measures a physical quantity of an object to be measured using a variable capacitor such as a capacitance type pressure sensor.

### BACKGROUND ART

The capacitance type pressure sensor is generally formed by a capacitor positioned between a diaphragm that moves under the influence of a received pressure and a fixed surface, and measures pressure by recognizing a change in pressure as a change of a capacitance of the capacitor.

For example, this kind of the pressure sensor, as mentioned in Prior Art References 1 and 2, is provided in a measuring chamber to which a gas or a liquid is introduced, by making one of the walls that form this measuring chamber the diaphragm. Moreover, by fixing a wiring substrate at a position opposed to this diaphragm, providing one electrode at an outer front surface of the diaphragm, providing the other electrode to a rear surface of the wiring substrate, and forming a variable capacitor for measuring pressure, the pressure sensor may be configured to measure the capacitance of this variable capacitor by a measuring circuit provided on the front surface of the wiring substrate.

Incidentally, since the variable capacitor has very high output impedance, it is necessary to have an impedance conversion element with a high impedance input port such as a buffer or an amplifier in the measuring circuit for the capacitance; however, a measuring circuit with such a high input impedance element tends to be influenced by environmental changes (e.g., temperature change or humidity change).

For example, if temperature or humidity changes and a leakage current or a stray capacitance occurs in the circuit portion between the impedance conversion element and the variable capacitor, the impedance changes and the measurement is greatly affected. Furthermore, a value of a reference electrical element that serves as a reference for measurement (for example, a reference capacitor of fixed volume or a reference resistor, etc.), changes under the influence of temperature or humidity, thereby the measurement is negatively influenced, in a similar manner.

Therefore, conventionally, by providing a guard ring to the circuit portion in order to prevent the leakage current or by sealing a wiring substrate in a casing in order to reduce the effect of environmental changes, measurement accuracy can be ensured.

### PATENT DOCUMENTS

Patent Document 1: Japanese Unexamined Patent Application Publication No. Hei 10-111206

Patent Document 1: U.S. Pat. No. 6,439,056

### SUMMARY OF THE INVENTION

### Problems to be Solved by the Invention

However, since wiring or electrical elements which are included in the measuring circuit are exposed to the front surface of the wiring substrate, there are limits to adopt the above mentioned countermeasures, and thus rapid improvement in the measurement accuracy cannot be expected. Moreover, since the electrical elements are merely supported by soldering, a defective contact may be generated by unexpected vibrations, etc. Of course, in a setting with a stable but extreme environment, such as is provided in a temperature controlled room, it may be possible to raise the measurement accuracy, but there is a possibility of enlarging the space required or complicating the structure.

The present invention is made to address the above discussed issues, and a primary object of this kind of capacitance type measuring device is a rapid improvement in measurement accuracy without increasing the size or complexity of the structure.

### BRIEF SUMMARY OF THE INVENTION

Accordingly, a capacitance type measuring device according to the present invention for measuring a physical quantity of an object to be measured by using a change of a capacitance of a variable capacitor is provided, which comprises and comprises a primary measuring circuit that is configured with the variable capacitor and a reference electronic element which serves as a reference to measure the capacitance of the variable capacitor, a secondary measuring circuit that has an impedance conversion element with sufficiently high input impedance and is connected to the primary measuring circuit, and a substrate in which a part or all of the each measuring circuit is formed, wherein a high impedance circuit part that is formed between the variable capacitor and the impedance conversion element, and the reference electronic element are formed by embedding in the inside between a front surface and a rear surface of the substrate.

With this configuration, since the high impedance circuit part that tends to be influenced by environmental changes and the reference electronic element can be placed inside of the substrate that is an extremely stable environment, it is possible to achieve a capacitance type measuring device that solves problems such as leakage current, stray capacitance, humidity, etc. and has stable efficiency with very high measurement accuracy. Additionally, since the high impedance circuit part and the reference electronic element are embedded within the substrate, this may contribute to the compactness and simplicity of the structure. Further, a defective contact also is unlikely to occur by unexpected external force such as vibration, etc., and thus robustness may be improved. An impedance conversion element with “well enough high input impedance” is one with a certain degree of the input impedance that does not substantially affect the output characteristics of an output element (for example, a variable capacitor) connected to this impedance conversion element.

The physical quantity of the object to be measured is the pressure of the gas or the liquid. The device is provided with a measuring chamber formed with a peripheral wall including a movable wall portion that is displaced by the pressure of the gas or the liquid introduced into the inside of the measuring chamber, and also is provided with a rear surface of the substrate opposed to the movable wall, and one electrode that is an output end of the variable capacitor is formed by the rear surface of the substrate, and another electrode of the variable capacitor is formed by the movable wall. Since the rear surface of the wiring substrate functions as an electrode of the variable capacitor, it is unnecessary to provide a wiring or a connector, etc. to connect the variable capacitor and the wiring substrate, and thus compactness and cost reduction can be achieved.

In an embodiment that can contribute to simplification of manufacture and compactness, etc., the substrate may be formed by laminating insulative thin sheets and the high impedance circuit part and the reference electronic element may be formed by filling an electrical conductor in a via and/or a groove provided in a part or all of the insulative thin sheet.

If the entirety of the measuring circuit is undesirably embedded inside of the substrate, waste will occur and manufacture will become more difficult and result in higher cost. In order to avoid such faults, it is desirable that other measuring circuits excluding the variable capacitor, the high impedance circuit part, and the reference electronic element are mounted on the front surface of the substrate.

It is not necessary to embed both the reference electronic element and the high impedance circuit part in the substrate, and thus only the high impedance circuit part or only the reference electronic element may be embedded in the substrate depending on a specified measurement accuracy or installation environment.

### Effects of the Invention

According to the present invention configured in this way, since the high impedance circuit part or the reference electronic element, both of which are easily influenced by environmental changes, can be placed in the extremely stable environment of the inside of the substrate, problems such as the leakage current, stray capacitance, and humidity can be solved and a capacitance type measuring device that has very high measurement accuracy and stabilized performance can be realized.

Additionally, since the high impedance circuit part or the reference electronic element is embedded in the substrate, a compact and simple structure can be achieved. Further, defective contacts are unlikely to occur due to unexpected external force such as vibration, etc., and thus robustness can be improved.

### BRIEF DESCRIPTION OF THE DRAWINGS

FIG. 1 is a partial vertical sectional view illustrating a pressure sensor according to a first embodiment of the present invention.

FIG. 2 is a partial sectional perspective view illustrating a wiring substrate laminated in ceramic thin sheets according to the same embodiment.

FIG. 3 is an electrical circuit diagram illustrating a measuring circuit according to the same embodiment.

FIG. 4 is an electrical circuit diagram illustrating a measuring circuit according to another embodiment of the present invention.

FIG. 5 is an electrical circuit diagram illustrating a measuring circuit according to still another embodiment of the present invention.

FIG. 6 is an electrical circuit diagram illustrating a measuring circuit according to yet another embodiment of the present invention.

### DETAILED DESCRIPTION OF THE EMBODIMENTS

Hereinafter, a pressure sensor 100, which is a capacitance type measuring device according to one embodiment according to the present invention, is described with reference to drawings.

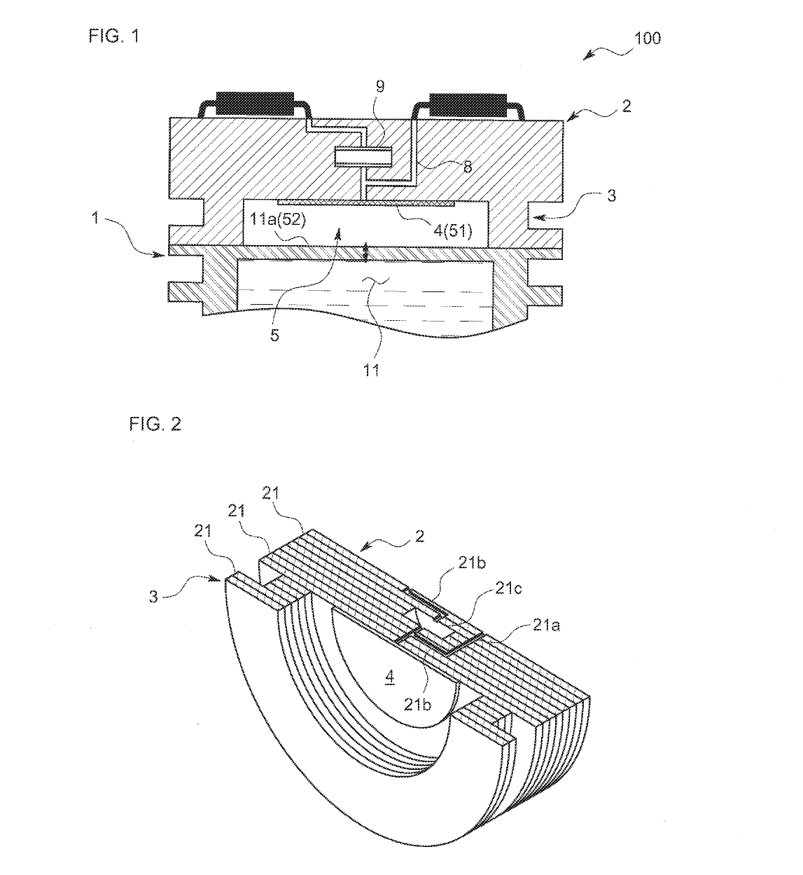

Pressure sensor 100 measures a pressure of a gas or a liquid, which is an object to be measured, and as shown in FIG. 1, pressure sensor 100 has a metal housing 1 that has electrical conductivity and a wiring substrate 2 that is attached to the housing 1.

Housing 1 is hollow and is provided with a measuring chamber 11 into an inside of which the gas or the liquid is introduced. An inlet port (not shown) for introducing the gas or the liquid into the measuring chamber 11 is provided on the bottom surface.

A diaphragm part 11a, which is a movable wall displaced in the thickness direction of a top wall according to the pressure of the gas or the liquid, is formed on the top wall of this measurement chamber 11. In addition, electrically, the diaphragm part 11a is maintained at the same voltage as minus common (ground), as described below.

The wiring substrate 2, as shown in FIG. 2, is in the shape of a board that is formed by laminating one or more ceramic thin sheets 21 having insulative properties, and a spacer 3 that is the shape of a pipe is protruded to a whole body from a rear surface peripheral edge part of the wiring substrate 2. And, for example, by brazing this spacer 3 at the top wall peripheral edge part of the measuring chamber 11, the rear surface of the wiring substrate 2 is arranged so that it is spaced a predetermined distance from and opposed to an outer front surface of the diaphragm part 11a. Furthermore, this spacer 3 is formed by laminating the annular ceramic thin sheets 21.

Furthermore, a metal plate 4 is attached to the rear surface of the wiring substrate 2. This metal plate 4 is used as one electrode 51, the diaphragm part 11a is used as the other electrode 52, and a variable capacitor 5 is formed by these components.

With this configuration, according to the pressure in the measuring chamber 11, the diaphragm part 11a is displaced, a distance to the metal plate 4 is changed, and the capacitance of the variable capacitor 5 is changed, so that the pressure of the gas or the liquid in the measuring chamber 11 is measurable by measuring the capacitance of this variable capacitor 5.

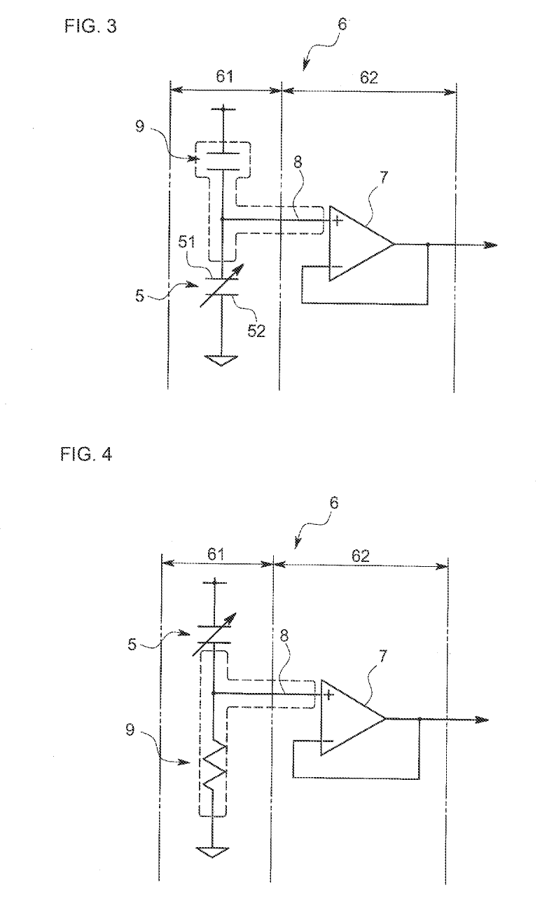

A measuring circuit 6 for measuring the pressure has a primary measuring circuit 61 and a secondary measuring circuit 62 as the electrical circuit diagram shows in FIG. 3. The primary measuring circuit 61 is configured with the variable capacitor 5 and a reference electronic element that becomes a reference for measuring the capacitance of the variable capacitor 5. The secondary measuring circuit 62 has an impedance conversion element with sufficiently high input impedance, and is connected to the primary measuring circuit 61.

Here, the reference electronic element is a fixed volume capacitor 9, and the capacitor 9 and the variable capacitor 5 are connected in series and provided between plus common (power source potential) and minus common (ground potential) such that the variable capacitor 5 is at the minus common side.

The impedance conversion element is for example an op amp 7 and is configured to function as an amplifier or a buffer. That is, one electrode 51 (i.e., the electrode connected to the capacitor 9), which is an output end of the variable capacitor 5, is connected to a plus input terminal of this op amp 7 and a minus terminal of the op amp 7 is connected to an output terminal of the op amp 7.

However, in this embodiment, a connecting line 8, which is a high impedance circuit part between the variable capacitor 5 and the plus input terminal of the op amp 7, and a capacitor 9 are formed so that they are embedded in the wiring substrate 2. It will be appreciated that the components in the region of the diagram surrounded with a dashed line in FIG. 3 are the components that are embedded in the wiring substrate 2.

Specifically, as shown in the perspective sectional view of FIG. 2, by providing a penetrating via (i.e., hole) 21a and a penetrating groove 21b in the ceramic thin sheets 21 that are configured as the wiring substrate 2, and filling up this penetration via 21a and the penetration groove 21b with a metal that is an electrical conductor, a connecting line 8 is formed inside of the wiring substrate 2.

For example, when extending the connecting line 8 in the thickness direction, the each individual penetrating via 21a in each ceramic thin sheet 21 may be arranged in the same location of each of the plurality of the laminated ceramic thin sheets 21 in order to make these penetration vias 21a continuously prolonged in the thickness direction. Further, when extending the connecting line 8 in parallel with the surface, a bottomed (or penetration) groove 21b may be formed on a portion of ceramic thin sheets 21.

Moreover, the capacitor 9 may be formed with a pair of metal foils, for example, by arranging a penetration via 21c with a predetermined size in the same location of each of the plurality of the laminated ceramic thin sheets 21 and forming metal foils on the upper and lower sides of the two ceramic thin sheets 21.

In addition, other electronic elements, for example, a resistor or an inductor can be formed by adjusting the form of the via and/or the groove or adjusting the electrical conductor material used to fill the vias and/or grooves.

According to the configuration of this embodiment, the high impedance circuit part 8, which tends to be influenced by environmental changes, and the capacitor 9, which is a reference electronic element, can be placed inside of a ceramic material that provides an extremely stable environment, and therefore it is possible to achieve a pressure sensor 100 that solves problems such as leakage current, stray capacitance, and humidity, etc., and has a stable efficiency with very high measurement accuracy.

Moreover, the rear surface itself of the wiring substrate 2 functions as an electrode of the variable capacitor 5, and therefore a wiring, connector, etc. that connects variable capacitor 5 and the wiring substrate 2 is rendered unnecessary and compactness and cost reduction can be achieved. Furthermore, the wiring substrate 2 and the spacer 3 can be formed all at once by laminating the ceramic thin sheets 21, which facilitates manufacture. Additionally, since the high impedance circuit part 8 and the capacitor 9 are embedded in the wiring substrate 2, defective contact is unlikely to occur by an unexpected external force such as vibration, etc., and robustness can be improved.

Moreover, since the spacer 3 is formed by laminating the ceramic thin sheets 21 and the height (gap) of this spacer can be easily controlled by the lamination number of the ceramic thin sheets 21, by adjusting this number, the capacity of the variable capacitor 5 can be controlled and a sensor suited a specified pressure range to be measured can be created at will and with ease.

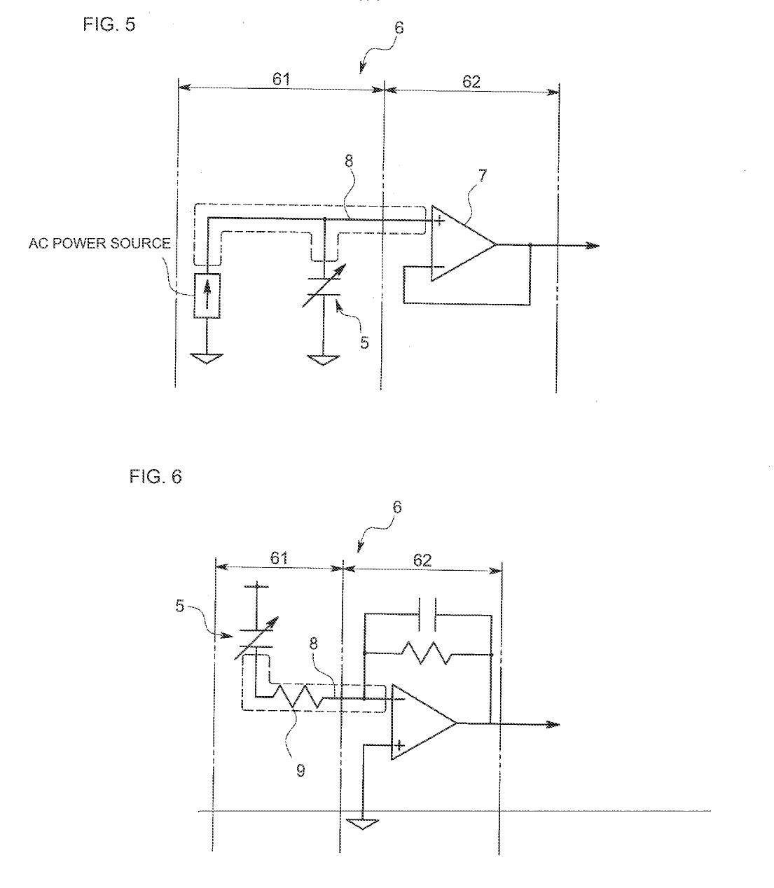

It will be appreciated that the present invention is not limited to the above described embodiment. For example, various modifications are possible for the measuring circuit 6 as exemplified in the FIG. 4 to FIG. 6. In FIG. 4 to FIG. 6, similar reference characters are given to corresponding components in the above embodiment. The reference electronic element 9, as it is also clear from FIG. 4 and FIG. 6, may be a resistor or an inductor, rather than a capacitor. Moreover, by applying the present invention to not only a pressure sensor but also various measuring devices that measure the physical quantity of an object to be measured using a change of capacitance, the same advantages can be achieved. In addition, the present invention is not limited to these embodiments, and it should be understood that various modifications may be possible without departing from the spirit and scope of the present invention.

### EXPLANATION OF REFERENCE CHARACTERS

100 Pressure sensor (Capacitance type measuring device)
11 Measuring chamber
11a Diaphragm part (Movable wall)
2 Wiring substrate (Substrate)
21 Ceramic thin sheets (Insulative thin sheets)
21a, 21c Via (hole)
21b Groove
5 Variable capacitor
51 One electrode
52 The other electrode
6 Measuring circuit
61 Primary measuring circuit 61
62 Secondary measuring circuit 62
7 Op amp (Impedance conversion element)
8 Connecting line (High impedance circuit part)
9 Capacitor (Reference electronic element)

We claim:

1. A capacitance type measuring device that measures a physical quantity of an object to be measured using a change of a capacitance of a variable capacitor comprising:
a primary measuring circuit that is configured with the variable capacitor and a reference electronic element that is a reference to measure the capacitance of the variable capacitor;
a secondary measuring circuit that has an impedance conversion element with sufficiently high input impedance and is connected to the primary measuring circuit; and
a substrate in which a part or all of each measuring circuit is formed;
wherein a high impedance circuit part that is formed between the variable capacitor and the impedance conversion element and the reference electronic element are provided inside of the substrate.

2. The capacitance type measuring device according to claim 1, wherein the reference electronic element is a fixed volume capacitor.

3. The capacitance type measuring device according to claim 1, wherein a physical quantity of the object to be measured is a pressure of a gas or a liquid, the capacitance type measuring device further comprising:
a measuring chamber formed to include a peripheral wall, a portion of the peripheral wall being a movable wall that is displaced by the pressure of the gas or the liquid introduced into an inside of the measuring chamber;
wherein a rear surface of the substrate is provided opposite the movable wall;
wherein one electrode that is an output end of a variable capacitor is formed at the rear surface of the substrate; and
wherein the other electrode of the variable capacitor is formed at the movable wall.

4. The capacitance type measuring device according to claim 1, wherein the substrate is formed by laminating one or more insulative thin sheets; and
wherein the high impedance circuit part and a reference electronic element are formed by filling an electrical conductor to a via or a groove provided to a part or all of the one or more insulative thin sheets.

5. The capacitance type measuring device according to claim 1, wherein another measuring circuit excluding the variable capacitor, the high impedance circuit part, and the reference electronic element is mounted on a front surface of the substrate.

6. A capacitance type measuring device for measuring a physical quantity of an object to be measured using a change of a capacitance of a variable capacitor, the device comprising:
a primary measuring circuit that is configured with the variable capacitor;
a secondary measuring circuit that has an impedance conversion element with sufficiently high input impedance and is connected to the primary measuring circuit; and
a substrate in which a part or all of the each measuring circuit is formed;
wherein a high impedance circuit part that is formed between the variable capacitor and the impedance conversion element is provided inside of the substrate.

7. A capacitance type measuring device for measuring a physical quantity of an object to be measured using a change of a capacitance of a variable capacitor, the device comprising:
a measuring circuit that is configured with the variable capacitor and a reference electronic element that is a reference to measure the capacitance of the variable capacitor; and
a substrate in which a part or all of the measuring circuit is formed;
wherein the reference electronic element is provided inside of the substrate.
